(19) United States
(12) Patent Application Publication
(10) Pub. No.: US 2020/0091198 A1
(43) Pub. Date: Mar. 19, 2020

(54) ARRAY SUBSTRATE, MANUFACTURING METHOD THEREOF, AND DISPLAY DEVICE

(71) Applicant: BOE TECHNOLOGY GROUP CO., LTD., Beijing (CN)

(72) Inventors: Kuanjun Peng, Beijing (CN); Feng Liao, Beijing (CN)

(21) Appl. No.: 15/751,131

(22) PCT Filed: Jul. 13, 2017
(86) PCT No.: PCT/CN2017/092781

§ 371 Date: Feb. 7, 2018

(30) Foreign Application Priority Data
Sep. 12, 2016 (CN) 201610817595.9

(51) Int. Cl. H01L 27/12; H01L 21/265

(52) U.S. Cl. CPC H01L 27/1225; H01L 29/7869; H01L 27/1248; H01L 21/2652

(57) ABSTRACT

The present disclosure relates to the technical field of display, and discloses an array substrate, a manufacturing method thereof, and a display device. The manufacturing method of the array substrate comprises: forming a first active layer, a material of which is polysilicon; injecting ions at least into an area to be doped of the first active layer to form a doped area, which is utilized to be electrically connected to corresponding source electrode and drain electrode; forming a second active layer, a material of which is an amorphous metal oxide; and after injecting ions at least into the area to be doped of the first active layer and forming the second active layer, performing an activation process to activate the ions injected into the first active layer and to convert the material of the second active layer from an amorphous state to a microcrystalline state.

### CROSS REFERENCE TO RELATED APPLICATIONS

The present application is the national phase of PCT Application No. PCT/CN2017/092781, filed on Jul. 13, 2017 which in turn claims a priority from Chinese Patent Application No. 201610817595.9, filed on Sep. 12, 2016, with a title of “Array substrate, manufacturing method thereof, and display device”, the entire contents thereof being incorporated herein by reference.

### TECHNICAL FIELD

The present disclosure relates to the technical field of display, and particularly to an array substrate, a manufacturing method thereof, and a display device.

### BACKGROUND

Currently, outdoor wearable display devices are popular with users. In order to improve user experience, outdoor wearable display devices need to meet various requirements such as low power consumption, sensor integration, narrow border, etc.

A display device typically comprises a package substrate and an array substrate. The array substrate is divided into a display area and a non-display area (also referred to as a perimeter area) surrounding the display area. In the non-display area, a low temperature poly-silicon thin film transistor (LTPS TFT) technique is used to achieve narrow border and sensor circuit integration; and in the display area, an amorphous oxide thin film transistor (Oxide TFT) technique is used to achieve low frequency pixel driving so as to lower power consumption, because amorphous Oxide TFT has a relatively low leakage current (I_{off}). However, amorphous Oxide TFT has a poor stability. In order to improve stability, microcrystalline Oxide TFT can be used in place of amorphous Oxide TFT. However, manufacturing process of LTPS TFT and manufacturing process of microcrystalline Oxide TFT are performed separately at present, resulting in low process integration level and high production cost.

### SUMMARY

Embodiments of the present disclosure comprise the following technical solutions.

In one aspect, provided is a manufacturing method of an array substrate, comprising:

forming a first active layer, a material of which is polysilicon;

injecting ions at least into an area to be doped of the first active layer to form a doped area, which is utilized to be electrically connected to corresponding source electrode and drain electrode;

forming a second active layer, a material of which is an amorphous metal oxide; wherein the step of forming a second active layer is performed after forming the first active layer and injecting ions at least into the area to be doped of the first active layer, or is performed before forming the first active layer; and

after injecting ions at least into the area to be doped of the first active layer and forming the second active layer, performing an activation process to activate the ions injected into the first active layer and to convert the material of the second active layer from an amorphous state to a microcrystalline state.

Optionally, the activation process is a thermal activation process.

Optionally, the activation process for activating the ions injected into the first active layer and converting the material of the second active layer from an amorphous state to a microcrystalline state comprises:

adjusting an ambient temperature for the array substrate to a temperature of 550° C.-650° C. and keeping the temperature for 0.5 h-1.0 h.

Optionally, the method further comprises:

forming a gate metal layer including a first gate electrode and a second gate electrode, wherein, the first gate electrode corresponds in position to the first active layer, and the second gate electrode corresponds in position to the second active layer;

forming a source and drain metal layer including a first source electrode, a first drain electrode, a second source electrode and a second drain electrode, wherein the first source electrode and the first drain electrode are electrically connected to the first active layer respectively, and the second source electrode and the second drain electrode are electrically connected to the second active layer respectively.

Optionally, the array substrate is divided into a display area and a non-display area surrounding the display area;

the first active layer, the first gate electrode, the first source electrode and the first drain electrode are all formed in the non-display area; and

the second active layer, the second gate electrode, the second source electrode and the second drain electrode are all formed in the display area.

Optionally, the ion injection comprises:

injecting ions only into the area to be doped of the first active layer.

Optionally, the injecting ions comprises plasma bombarding.

Optionally, the metal oxide of the second active layer is zinc oxide, or a metal oxide in which zinc oxide is doped with at least one of indium, gallium, tin and magnesium.

Optionally, the manufacturing method is carried out in a sequence of: forming the first active layer, forming the gate metal layer, injecting ions at least into the area to be doped of the first active layer, forming the second active layer, performing the activation process, and forming the source and drain metal layer.

Optionally, the method further comprises:

forming a gate insulating layer overlaying the first active layer, after said forming the first active layer and before said forming the gate metal layer.

Optionally, the method further comprises:

forming an interlayer dielectric layer overlaying the gate metal layer, after said injecting ions at least into the area to be doped of the first active layer and before said forming the second active layer.

In another aspect, provided is an array substrate formed by the manufacturing method according to any one of the above technical solutions.

In yet another aspect, provided is a display device comprising the array substrate described above.

In still yet another aspect, provided is a complementary metal oxide semiconductor (CMOS) device comprising the array substrate described above.

### BRIEF DESCRIPTION OF DRAWINGS

To more clearly illustrate the technical solutions in the embodiments of the present disclosure or in prior art, the drawings to be used in the description of the embodiments or prior art will be briefly introduced below. Obviously, the following descriptions of the drawings are only some embodiments of the present disclosure, and other drawings can be obtained by those skilled in the art according to these drawings without inventive efforts.

FIG. 1 is a flow chart I of a manufacturing method of an array substrate provided in an embodiment of the present disclosure;

FIG. 2 is a structural schematic diagram of an array substrate provided in an embodiment of the present disclosure; and

FIG. 3 is a flow chart II of a manufacturing method of an array substrate provided in an embodiment of the present disclosure.

### REFERENCE NUMBER LIST

1-first Thin Film Transistor TFT1; 2-second Thin Film Transistor TFT2; 3-display area; 4-non-display area; 5-gate insulating layer; 6-interlayer dielectric layer; 7-substrate; 8-planar layer; 11-first active layer; 111, 112-doped zone; 12-first gate electrode; 13-first source electrode; 14-first drain electrode; 21-second active layer; 22-second gate electrode; 23-second source electrode; and 24-second drain electrode.

### DETAILED DESCRIPTION

The technical solutions in embodiments of the present disclosure will be detailedly described below in combination with the drawings of the embodiments of the present disclosure. Obviously, the embodiments described are only a part of, not all of the embodiments of the present disclosure. All of other embodiments obtained by those skilled in the art based on the embodiments described, without inventive efforts, fall within the protection scope of the present disclosure.

In the description of the present disclosure, it should be understood that direction or position relationship indicated by the term “above”, “below” or the like is described on the basis of the direction or position relationship shown in figure(s), and it is only for the purpose of describing the present disclosure conveniently and simplifying the description, but it does not indicate or imply that the referred device or member must have a particular direction or position, or be constructed or operated in a particular direction or position. As a result, it should not be interpreted as limiting the present disclosure.

### EMBODIMENT I

This embodiment provides a manufacturing method of an array substrate, comprising:

S01: forming a first active layer, a material of which is polysilicon. The process for forming the first active layer is not particularly limited here. For example, an amorphous silicon thin film can be formed first, and then the amorphous silicon thin film is irradiated with laser to crystalize the amorphous silicon (a-silicon) to polysilicon (p-silicon), thereby forming a polysilicon thin film.

S02: injecting ions at least into an area to be doped of the first active layer to form a doped area, which is utilized to be electrically connected to corresponding source electrode and drain electrode. The process for injecting ions and the type of ions injected are not limited here. For example, boron ions can be injected into the first active layer by plasma bombarding, to form a P-type TFT; or phosphorus ions can be injected into the first active layer by plasma bombarding, to form an N-type TFT. Of course, other ions can also be injected by other process, and the above process is only described as an example here.

S03: forming a second active layer, a material of which is an amorphous metal oxide. The material of the metal oxide is not particularly limited here, and can be determined according to actual situations. It should be noted that metal oxide can be classified into amorphous state, microcrystalline state and the like, depending on the crystalline state. TFT formed with microcrystalline metal oxide has lower leakage current, better I-V (current-voltage) characteristic and better stability compared with TFT formed with amorphous metal oxide.

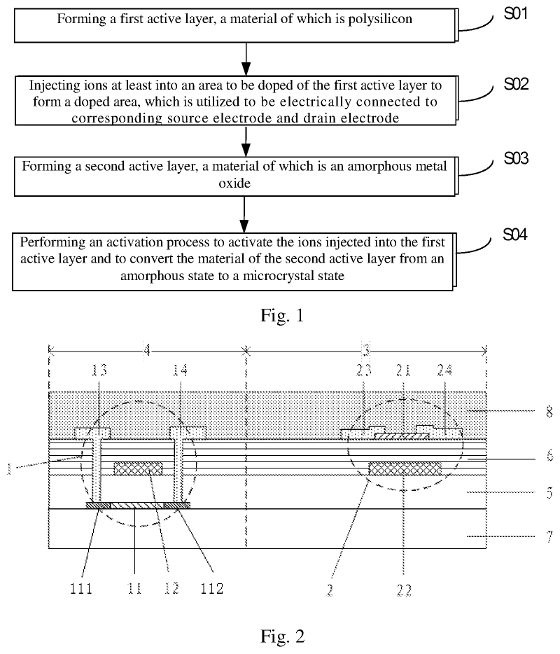

It should be noted that the above-mentioned S03 can be performed after S01 and S02, or before S01 and S02, which is not limited here. In order to prevent ion injection from affecting the formation of the second active layer, it can be selected to perform S03 after S01 and S02, as shown in FIG. 1.

S04: performing an activation process to activate the ions injected into the first active layer and to convert the material of the second active layer from an amorphous state to a microcrystalline state (i.e. from a-metal oxide to uc-metal oxide), after S02 injecting ions at least into an area to be doped of the first active layer and S03 forming a second active layer.

By the above manufacturing method, a conversion of the material of the second active layer from an amorphous state to a microcrystalline state can be achieved at the same time of performing an activation process to activate the ions injected into the first active layer. That is, the ion activation process of LTPS TFT and the process in which Oxide TFT is converted from an amorphous state to a microcrystalline state are integrated together, so that it has characteristics of high process integration level and low production cost relative to prior art.

Optionally, the above method further comprises:

S05: forming a gate metal layer including a first gate electrode and a second gate electrode, wherein, the first gate electrode corresponds in position to the first active layer, and the second gate electrode corresponds in position to the second active layer. The process for forming the gate metal layer is not particularly limited here. For example, in view of lowering cost, the first gate electrode and the second gate electrode can be formed through one-step patterning process, and the material of the first gate electrode and the second gate electrode can be a metal such as Al (aluminum), Mo (molybdenum), Cr (chromium), Cu (copper), Ti (titanium) and the like. The first gate electrode can be formed above the first active layer (top gate structure), or beneath the first active layer (bottom gate structure); and the second gate electrode can be formed above the second active layer (top gate structure), or beneath the second active layer (bottom gate structure).

S06: forming a source and drain metal layer including a first source electrode, a first drain electrode, a second source electrode and a second drain electrode, wherein the first source electrode and the first drain electrode are electrically connected to the first active layer respectively, and the second source electrode and the second drain electrode are electrically connected to the second active layer respectively. The process for forming the source and drain metal layer is not particularly limited here. For example, in view of lowering cost, the first source electrode, the first drain electrode, the second source electrode and the second drain electrode can be formed through one-step patterning process, and the material of the source and drain metal layer can be a metal such as Al (aluminum), Mo (molybdenum), Cr (chromium), Cu (copper), Ti (titanium) and the like.

It should be noted that the sequence of the above S05, S06 and S01-S04 is associated with the structure of TFT to be formed according to actual demand. The TFT can have a top gate structure (i.e. the gate electrode is formed above the active layer), or a bottom gate structure (i.e. the gate electrode is formed beneath the active layer), which is not limited here. For the convenience of description, TFT formed from the first active layer, the first gate electrode, the first source electrode and the first drain electrode is referred to as first thin film transistor (TFT1), and TFT formed from the second active layer, the second gate electrode, the second source electrode and the second drain electrode is referred to as second thin film transistor (TFT2). As shown in FIG. 2, TFT1 is a top gate TFT comprising a first active layer 11, a first gate electrode 12, a first source electrode 13 and a first drain electrode 14; and TFT2 is a bottom gate TFT comprising a second active layer 21, a second gate electrode 22, a second source electrode 23 and a second drain electrode 24. If the structure as shown in FIG. 2 is to be formed, the above method can be carried out in a sequence of: S01: forming a first active layer 11; S05: forming a gate metal layer, i.e. the first gate electrode 12 and the second gate electrode 22; S02: injecting ions at least into an area to be doped of the first active layer 11 to form doped areas 111, 112; S03: forming a second active layer 21; S04: performing an activation process; and S06: forming a source and drain metal layer comprising a first source electrode 13, a first drain electrode 14, a second source electrode 23 and a second drain electrode 24. Of course, the above TFT1 and TFT2 can also have other structures. The embodiments and drawings of the present disclosure are described with the structure shown in FIG. 2 as an example.

Optionally, as shown in FIG. 2, the above array substrate is divided into a display area 3 and a non-display area 4 surrounding the display area. The first active layer 11, the first gate electrode 12, the first source electrode 13 and the first drain electrode 14 (i.e. TFT1) are all formed in the non-display area 4. In the non-display area, a gate line drive circuit (also referred to as GOA circuit), a data line drive circuit, a sensor and the like are typically disposed. The above TFT1 is applied in these drive circuits or multiplexer, which is beneficial to achieve narrow border and sensor circuit integration. The second active layer 21, the second gate electrode 22, the second source electrode 23 and the second drain electrode 24 (i.e. TFT2) are all formed in the display area 3, which is beneficial to achieve low frequency pixel driving so as to lower power consumption. Furthermore, the above TFT1 and TFT2 can also be used for forming a complementary metal oxide semiconductor (CMOS) device, such as CMOS inverter and the like, which is not limited here and can be particularly determined according to actual situations.

Optionally, in order to ensure conductive effect, S02 injecting ions at least into an area to be doped of the first active layer particularly comprises injecting ions only into the area to be doped of the first active layer, wherein the doped area formed is utilized to be electrically connected to the first source electrode and the first drain electrode.

Optionally, S04 performing an activation process to activate the ions injected into the first active layer and to convert the material of the second active layer from an amorphous state to a microcrystalline state comprises:

adjusting an ambient temperature for the array substrate to a temperature of 550° C.-650° C. and keeping the temperature for 0.5 h-1.0 h. That is, a high temperature activation process is mainly employed to achieve ion activation of the doped area of the first active layer and the conversion of the material of the second active layer from an amorphous state to a microcrystalline state. For example, the ambient temperature may be about 600° C., and the duration may be about 1.0 h. The particular temperature and time can be determined according to actual situations.

Optionally, the metal oxide can be zinc oxide (ZnO) or a metal oxide in which zinc oxide is doped with at least one of indium, gallium, tin and magnesium, such as indium gallium zinc oxide (IGZO), indium tin zinc oxide (ITZO), magnesium indium zinc oxide (MIZO), indium zinc oxide (IZO) and the like. Of course, zinc oxide can also be doped with other metals, and the above metals are only described as examples here.

Optionally, the above method is carried out in a sequence of: S01: forming a first active layer 11; S05: forming a gate metal layer, i.e. the first gate electrode 12 and the second gate electrode 22; S02: injecting ions at least into an area to be doped of the first active layer to form doped areas 111, 112; S03: forming a second active layer 21; S04: performing an activation process; and S06: forming a source and drain metal layer comprising a first source electrode 13, a first drain electrode 14, a second source electrode 23 and a second drain electrode 24, so as to form the structure shown in FIG. 2. It should be noted that, as shown in FIG. 2, the doped areas 111, 112 of the first active layer 11 refer to portions not shielded by the first gate electrode 12. Because of the shielding effect of the first gate electrode 12, it can be easily achieved to inject ions only into doped areas 111, 112 of the first active layer 11 with the above manufacture sequence.

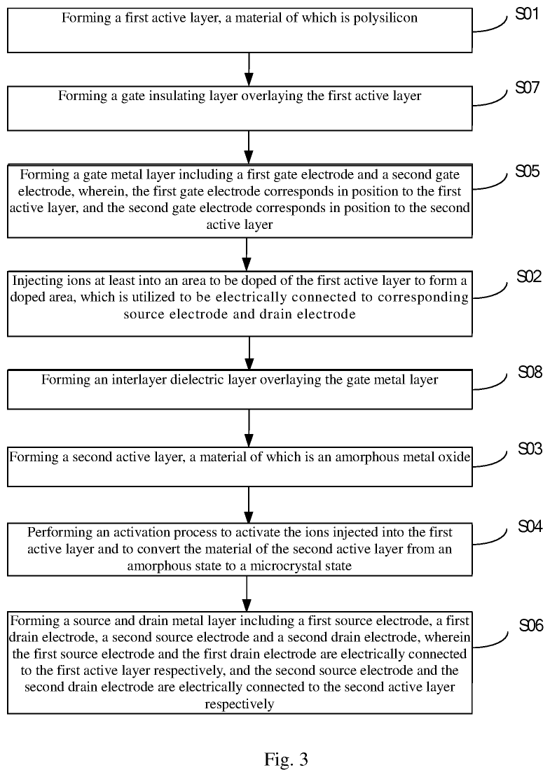

Optionally, as shown in FIG. 3, the above method further comprises:

S07: forming a gate insulating layer 5 overlaying the first active layer 11 as shown in FIG. 2 to protect the first active layer 11, after S01 forming a first active layer 11 and before S05 forming a gate metal layer. The forming manner of the gate insulating layer 5 is not particularly limited here. For example, chemical vapor deposition (CVD) process can be used to form the gate insulating layer 5, and the material of the gate insulating layer 5 can be an insulating material such as silicon oxide, silicon nitride, an organic material and the like.

S08: forming an interlayer dielectric layer 6 (also referred to as ILD layer) overlaying the gate metal layer (i.e. the first gate electrode 12 and the second gate electrode 22) as shown in FIG. 2 to protect the gate metal layer, after S02 injecting ions at least into an area to be doped of the first active layer 11 and before S03 forming a second active layer 12. The material of the interlayer dielectric layer can be an insulating material such as silicon oxide, silicon nitride, an organic material and the like.

The above array substrate can further comprise a substrate 7 as shown in FIG. 2, and both TFT1 and TFT2 are formed on the substrate 7. Of course, in order to generate an electric field, the above array substrate can also comprise a pixel electrode and/or a common electrode. Further, in order to protect the first active layer of TFT1 from light, the above array substrate can also comprise a light shield layer disposed beneath the first active layer of TFT1, etc. Only structures related to the merits of the invention are described in detail here, and reference can be made to prior art for remaining structures.

By the manufacturing method of the array substrate according to the present disclosure, when performing an activation process to activate the ions injected into the first active layer, a conversion of the material of the second active layer from an amorphous state to a microcrystalline state can be achieved at the same time. That is, the ion activation process of LTPS TFT and the process in which Oxide TFT is converted from an amorphous state to a microcrystalline state are integrated together. This method has characteristics of high process integration level and low production cost relative to prior art.

### EMBODIMENT II

This embodiment provides an array substrate formed by any manufacturing method provided in Embodiment I. The array substrate has characteristics of high process integration level and low production cost. The array substrate can be an ordinary array substrate or a color filter on Array (COA) substrate which refers to a substrate in which a color film layer is made on an array substrate, and it is not limited here.

Array substrates with various structures can be formed by adjusting the sequence of the manufacturing method in Embodiment I. An array substrate with a particular structure is provided below. As shown in FIG. 2, the array substrate comprises: a substrate 7; and a first active layer 11 (including doped areas 111, 112), a gate insulating layer 5 overlaying the first active layer 11, a gate metal layer (a first gate electrode 12 and a second gate electrode 22), an interlayer dielectric layer 6 overlaying the gate metal layer, and a source and drain metal layer, which are sequentially disposed on the substrate 7; wherein, the source and drain metal layer comprises a first source electrode 13, a first drain electrode 14, a second source electrode 23 and a second drain electrode 24, the first source electrode 13 and the first drain electrode 14 are electrically connected to the first active layer 11 through a via hole penetrating the interlayer dielectric layer 6 and the gate insulating layer 5, and the second source electrode 23 and the second drain electrode 24 are electrically connected to the second active layer 21 through direct contact. Of course, for the convenience of manufacturing subsequent film layers such as pixel electrode, common electrode and the like, the above array substrate can further comprise a planar layer 8 overlaying the source and drain metal layer, as shown in FIG. 2, wherein the planar layer has functions of planarization and insulation, and the material for the planar layer can be an organic insulating material.

### EMBODIMENT III

This embodiment provides a display device comprising the array substrate provided in Embodiment II. The display device can be a display apparatus, such as liquid crystal display, electronic paper, organic light-emitting diode (OLED) display and the like, or any product or component with display function comprising the above display apparatus, such as television, digital camera, mobile phone, tablet computer and the like. The display device has characteristics of high process integration level, low production cost, low power consumption and high stability. Furthermore, the size and application scene of the display device are not limited here. The display device can be a large size display device, or a small size wearable display device such as wristband and the like. The display device can be applied indoor or outdoor. The display device is more advantageous when applied outdoor due to its low power consumption.

The above descriptions are only some particular embodiments of the present disclosure, but the protection scope of the present application is not limited thereto. Within the technical scope disclosed in the present disclosure, one skilled in the art can readily envisage variations and alternatives, and all of them are covered by the protection scope of the present application. Therefore, the protection scope of the present application is defined by the claims.

Please amend claims

1

,

3

,

4

,

6

-

9

,

11

and

12

, and add new claims

15

-

20

, such that the status of the claims is as follows:

1. A manufacturing method of an array substrate, comprising:
forming a first active layer, a material of which is polysilicon;
injecting ions at least into an area to be doped of the first active layer to form a doped area, which is utilized to be electrically connected to a corresponding source electrode and drain electrode;
forming a second active layer, a material of which is an amorphous metal oxide, wherein the step of forming the second active layer is performed after forming the first active layer and injecting ions at least into the area to be doped of the first active layer, or is performed before forming the first active layer; and
after injecting ions at least into the area to be doped of the first active layer and forming the second active layer, performing an activation process to activate the ions injected into the first active layer and to convert the material of the second active layer from an amorphous state to a microcrystalline state.

2. The manufacturing method according to claim 1, wherein the activation process is a thermal activation process.

3. The manufacturing method according to claim 1 or 2, wherein the activation process for activating the ions injected into the first active layer and converting the material of the second active layer from an amorphous state to a microcrystalline state comprises:
adjusting an ambient temperature for the array substrate to a temperature of 550° C.-650° C. and keeping the temperature for 0.5 h-1.0 h.

4. The manufacturing method according to claim 1, wherein the method further comprises:
forming a gate metal layer including a first gate electrode and a second gate electrode, wherein, the first gate electrode corresponds in position to the first active layer, and the second gate electrode corresponds in position to the second active layer; and
forming a source and drain metal layer including a first source electrode, a first drain electrode, a second source electrode and a second drain electrode, wherein the first source electrode and the first drain electrode are electrically connected to the first active layer respectively, and the second source electrode and the second drain electrode are electrically connected to the second active layer respectively.

5. The manufacturing method according to claim 4, wherein
the array substrate is divided into a display area and a non-display area surrounding the display area;
the first active layer, the first gate electrode, the first source electrode and the first drain electrode are all formed in the non-display area; and
the second active layer, the second gate electrode, the second source electrode and the second drain electrode are all formed in the display area.

6. The manufacturing method according to claim 1, wherein said injecting ions comprises:
injecting ions only into the area to be doped of the first active layer.

7. The manufacturing method according to claim 1, wherein said injecting ions comprises plasma bombarding.

8. The manufacturing method according to claim 1, wherein the metal oxide is zinc oxide, or a metal oxide in which zinc oxide is doped with at least one of indium, gallium, tin and magnesium.

9. The manufacturing method according to claim 4, wherein the manufacturing method is carried out in a sequence of: forming the first active layer, forming the gate metal layer, injecting ions at least into the area to be doped of the first active layer, forming the second active layer, performing the activation process, and forming the source and drain metal layer.

10. The manufacturing method according to claim 9, wherein the method further comprises:
forming a gate insulating layer overlaying the first active layer, after said forming the first active layer and before said forming the gate metal layer.

11. The manufacturing method according to claim 9, wherein the method further comprises:
forming an interlayer dielectric layer overlaying the gate metal layer, after said injecting ions at least into the area to be doped of the first active layer and before said forming the second active layer.

12. An array substrate formed by the manufacturing method according to claim 1.

13. A display device comprising the array substrate according to claim 12.

14. A complementary metal oxide semiconductor (CMOS) device comprising the array substrate according to claim 12.

15. The array substrate according to claim 12, wherein the array substrate includes a display area and a non-display area surrounding the display area, the first active layer is formed in the non-display area, and the second active layer is formed in the display area.

16. The array substrate according to claim 15, wherein the non-display area includes a low temperature poly-silicon thin film transistor, and the display area includes a microcrystalline oxide thin film transistor.

17. The display device according to claim 13, wherein the array substrate includes a display area and a non-display area surrounding the display area, the first active layer is formed in the non-display area, and the second active layer is formed in the display area.

18. The display device according to claim 17, wherein the non-display area includes a low-temperature poly-silicon thin film transistor, and the display area includes a microcrystalline oxide thin film transistor.

19. The CMOS device according to claim 14, wherein the array substrate includes a display area and a non-display area surrounding the display area, the first active layer is formed in the non-display area, and the second active layer is formed in the display area.

20. The CMOS device according to claim 19, wherein the non-display area includes a low temperature poly-silicon thin film transistor, and the display area includes a microcrystalline oxide thin film transistor.
